(19) United States
(12) Patent Application Publication
(10) Pub. No.: US 2007/0111413 A1
(43) Pub. Date: May 17, 2007

(54) Method for fabricating semiconductor device

(75) Inventor: Song Hyeuk Im, Chungcheongbuk-do (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/481,336

(22) Filed: Jul. 3, 2006

(30) Foreign Application Priority Data
Nov. 17, 2005 (KR) 10-2005-0110270

(51) Int. Cl. H01L 21/338

(52) U.S. Cl. 438/167

(57) ABSTRACT

A method for fabricating a semiconductor device comprises forming a first recess in a semiconductor substrate having a device isolation structure defining an active region, forming a nitride film over an entire surface of the resultant including the first recess, etching the nitride film at the bottom of the first recess to expose the semiconductor substrate at the bottom of the first recess, oxidizing the semiconductor substrate exposed at the bottom of the first recess to form an oxide film, and removing the oxide film and the nitride film to form a second recess.

### CROSS-REFERENCES TO RELATED APPLICATIONS

The present application claims priority to Korean patent application No. 10-2005-0110270, filed on Nov. 17, 2005, which is incorporated by reference in its entirety.

### BACKGROUND OF THE INVENTION

The present invention relates to a method for fabricating a semiconductor device, wherein a semiconductor substrate at a bottom of a recess formed in the semiconductor substrate is oxidized, and removed to increase a channel length of a recess gate, thereby improving a short channel effect. Accordingly, characteristics of the device and its reliability can be improved.

According to recent trends using highly integrated semiconductor devices, a planner gate of a highly integrated semiconductor device has a problem such as a short channel effect.

A recess gate has been used, which is formed by etching a semiconductor substrate under a gate, so as to improve a refresh characteristic of the device and to increase a channel length. However, an effective channel length of the recess gate is reduced when a depth of a junction region in the device is increased. Since an E-field is formed at a sidewall of the recess gate, the refresh characteristic of the device is degraded. As a result of increasing the depth of the junction region, a leakage current is increased.

FIG. 1 is a simplified layout of a conventional semiconductor device, wherein reference numerals 1 and 3 denote an active region defined by a device isolation structure 20 and a gate region, respectively.

FIGS. 2a through 2c are simplified cross-sectional views illustrating a conventional method for fabricating a semiconductor device.

Referring to FIG. 2a, a semiconductor substrate 10 having a pad insulating film (not shown) is etched using a device isolation mask (not shown) defining a device isolation structure 20 shown in FIG. 1 to form a trench (not shown). The trench is filled with an insulating film (not shown) to form the device isolation structure 20. The pad insulating film is removed to expose an active region 1 shown in FIG. 1. A hard mask layer 25 is formed over an entire surface of the resultant.

Referring to FIG. 2b, a photoresist film (not shown) is formed over the hard mask layer 25. The photoresist film is exposed and developed using a recess gate mask (not shown) defining a gate region 3 shown in FIG. 1 to form a photoresist film pattern 30. The hard mask layer 25 is etched using the photoresist film pattern 30 to form a recess region 40 exposing the semiconductor substrate 10 of the gate region 3 shown in FIG. 1.

Referring to FIG. 2c, the photoresist film pattern 30 is removed. A predetermined thickness of the semiconductor substrate 10 exposed at the recess region 40 is etched to form a recess 50. The hard mask layer 25 is removed to expose the semiconductor substrate 10 including the recess 50. Here, a gate channel is formed at a predetermined portion of the semiconductor substrate 10 in the recess 50 in a subsequent process. Accordingly, a silicon horn at the semiconductor substrate 10 near to the device isolation structure 20 shown in FIG. 1 causes from increase in the etching time for forming the recess 50 in order to increase the gate channel length. As a result, threshold voltage of the device is lowered, thereby degrading the refresh characteristic of the device.

FIG. 3 is a simplified cross-sectional view of a conventional semiconductor device, wherein FIG. 3(i) is a simplified cross-sectional view taken along the line I-I′ of FIG. 1, and FIG. 3(ii) is a simplified cross-sectional view taken along the line II-II′ of FIG. 1. In a longitudinal direction (i.e., along line II-II′) of the gate region 3 shown in FIG. 1, the etch rate of the semiconductor substrate 10 near to the device isolation structure 20 is less than that of the semiconductor substrate 10 separated from the device isolation structure 20 by a predetermined distance, which results in forming a silicon horn in the recess 50.

According to the above conventional method for fabricating a semiconductor device, if the etching time for the recess is increased in order to increase the channel length of the device, the silicon horn occurs in the recess, thereby degrading the device characteristics and its reliability.

### BRIEF SUMMARY OF THE INVENTION

The present invention relates to a method for fabricating a semiconductor device, wherein a semiconductor substrate at a bottom of a recess formed in the semiconductor substrate is oxidized, and removed to increase a channel length of a recess gate, thereby improving a short channel effect. Accordingly, characteristics of the device and its reliability can be improved.

According to an embodiment of the present invention, a method for fabricating a semiconductor device comprises: (a) forming a first recess in a semiconductor substrate having a device isolation structure defining an active region; (b) forming a nitride film over an entire surface of the resultant including the first recess; (c) etching the nitride film at the bottom of the first recess to expose the semiconductor substrate at the bottom of the first recess; (d) oxidizing the semiconductor substrate exposed at the bottom of the first recess to form an oxide film; and (e) removing the oxide film and the nitride film to form a second recess, wherein a width of a lower part of the second recess is greater than that of an upper part of the second recess in a longitudinal direction of the active region.

In one embodiment, a method for fabricating a semiconductor device comprises forming a first recess in a semiconductor substrate. The first recess has a bottom and a sidewall. The recess is formed within an active region defined by the semiconductor substrate. An insulating film is formed over the substrate and the first recess. The second insulating film is etched to expose a portion of the substrate provided directly below the bottom of the first recess. The exposed semiconductor substrate at the bottom of the first recess is oxidized to form an oxide film. The oxide film is removed to form a second recess, wherein a lower portion of the second recess is larger than that of the first recess. The insulating film remains on the sidewall of the first recess after the etching step. A width of the lower portion of the second recess is greater than that of an upper portion of the second recess in a longitudinal direction of the active region. The insulating film is a nitride film.

### BRIEF DESCRIPTION OF THE DRAWINGS

FIG. 1 is a simplified layout of a conventional semiconductor device.

FIGS. 2a through 2c are simplified cross-sectional views illustrating a conventional method for fabricating a semiconductor substrate.

FIG. 3 is a simplified cross-sectional view illustrating a conventional semiconductor device.

FIG. 4 is a simplified layout of a semiconductor device according to one embodiment of the present invention.

FIGS. 5a through 5e are simplified cross-sectional views illustrating a method for fabricating a semiconductor device according to one embodiment of the present invention.

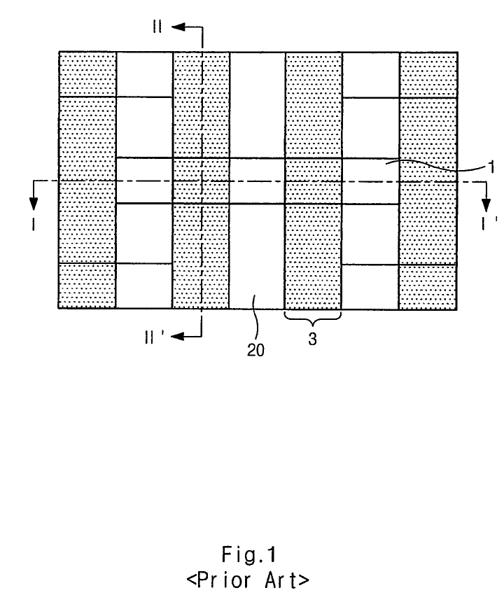

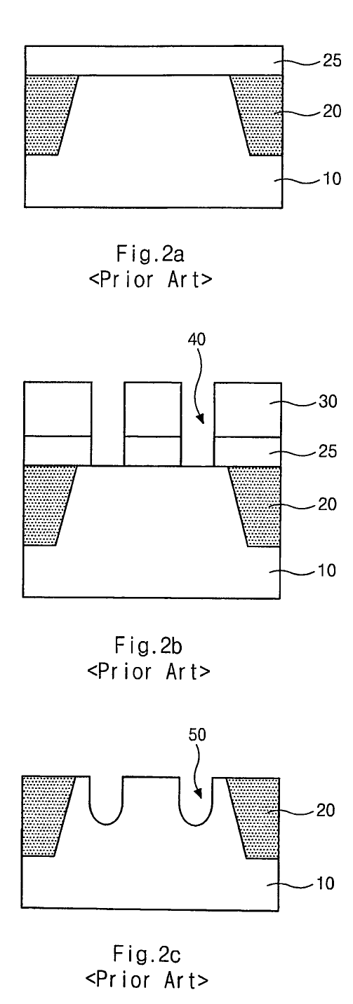

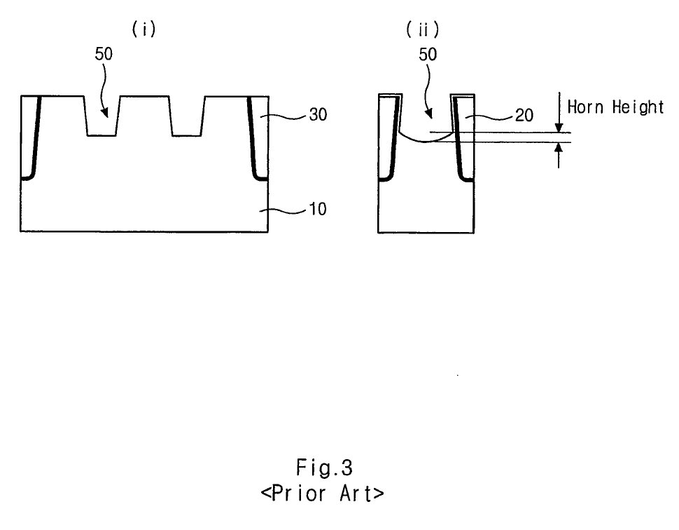

### DESCRIPTION OF SPECIFIC EMBODIMENT

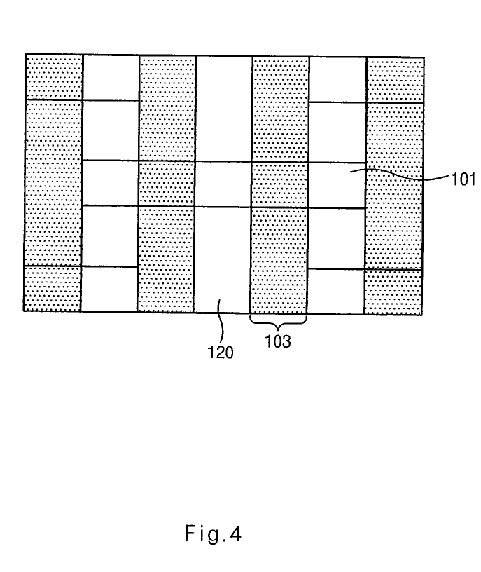

FIG. 4 is a simplified layout of a semiconductor device according to one embodiment of the present invention, wherein reference numerals 101 and 103 denote an active region defined by a device isolation structure 120 and a gate region, respectively.

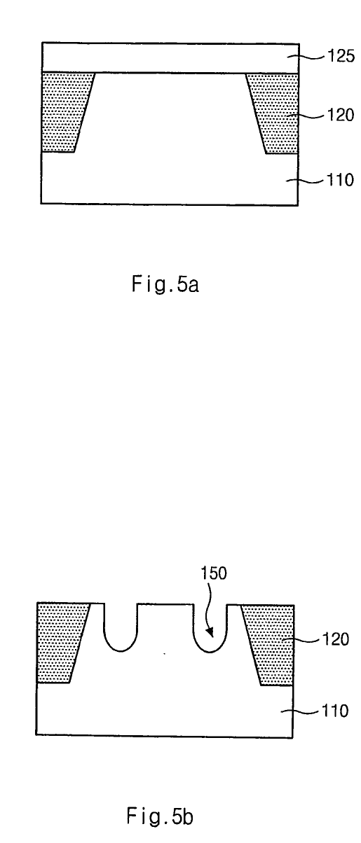

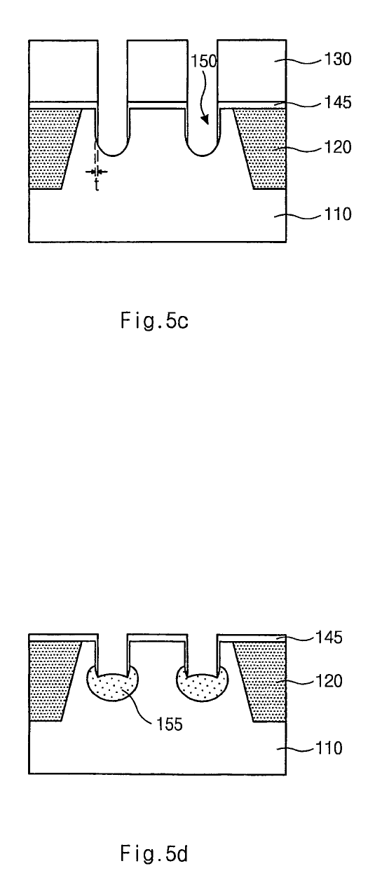

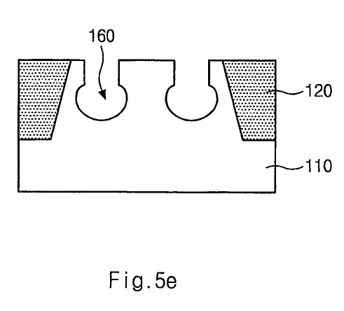

Figs. 5a through 5e are simplified cross-sectional views illustrating a method for fabricating a semiconductor device according to an embodiment of the present invention.

Referring to FIG. 5a, a semiconductor substrate 110 having a pad insulating film (not shown) is etched using a device isolation mask (not shown) defining a device isolation structure 120 shown in FIG. 4 to form a trench (not shown). The trench is filled with an insulating film for device isolation (not shown) to form the device isolation structure 120. The pad insulating film is removed to an active region 101 shown in FIG. 4. A hard mask layer 125 is formed over an entire surface of the resultant. In one embodiment of the present invention, the hard mask layer 125 is formed of a polysilicon layer.

Referring to FIG. 5b, a photoresist film (not shown) is formed over the hard mask layer 125. The photoresist film is exposed and developed using a recess gate mask (not shown) defining a gate region 103 shown in FIG. 4 to form a photoresist film pattern (not shown). The hard mask layer 125 is etched using the photoresist film pattern to form a recess region (not shown) exposing the semiconductor substrate 110 of the gate region 103 shown in FIG. 4. After the photoresist film pattern is removed, a predetermined thickness of the semiconductor substrate 110 exposed at the recess region is etched to form a first recess 150. The hard mask layer 125 is removed to expose the semiconductor substrate 110 including the first recess 150.

Referring to FIG. 5c, a nitride film 145 is formed over the exposed semiconductor substrate 110 including the first recess 150. A photoresist film (not shown) is formed over an entire surface of the resultant. The photoresist film is exposed and developed using the recess gate mask defining the gate region 103 shown in FIG. 4 to form a photoresist film pattern 130 exposing the nitride film 145 at the bottom of the first recess 150. The exposed nitride film 145 is etched to expose the semiconductor substrate 110 at the bottom of the first recess 150. In one embodiment of the present invention, a thickness of the nitride film 145 from the top surface of the semiconductor substrate 110 ranges from about 300° Å to about 500 Å. In addition, a width of the first recess 150 exposed between the photoresist film patterns 130 in a longitudinal direction of the active region 101 shown in FIG. 4 is less than that of the recess gate mask, so that a predetermined thickness t of the nitride film 145 remains at a sidewall of the first recess 150. At this time, the predetermined thickness t of the nitride film 145 remaining at the sidewall of the first recess 150 is at most about 100 Å. In another embodiment, the etching process for the nitride film 145 exposed at the bottom of the first recess 150 is performed by an anisotropic over-etching method.

Referring to FIGS. 5d and 5e, the photoresist film pattern 130 is removed. The semiconductor substrate 110 exposed at the bottom of the first recess 150 is oxidized to form an oxide film 155. The oxide film 155 and the nitride film 145 are removed to form a second recess 160. In one embodiment of the present invention, the oxidizing process for the semiconductor substrate 110 exposed at the bottom of the first recess 150 is performed by a LOCOS oxidation method. In addition, the oxidizing process is performed under an atmosphere of H₂:O₂ mixture gas, which a ratio of the mixture gas ranges from 7˜9:4˜6, at a temperature ranging from about 1000° C. to about 1100° C. for about 30 minutes to about 50 minutes. Here, a bird's beak is formed on the end of the nitride film 145 at the bottom of the first recess 150 to form an oxide film 155 on the semiconductor substrate 110 inside the nitride film 145 formed at the sidewall of the first recess 150 in a vertical direction, which is caused from a stress of the oxidizing process. In addition, a size of the oxide film 155 at the bottom of the first recess 150 can be adjusted according to controlling the oxidizing time. As a result, the channel length of the device can be adjusted. In another embodiment, the oxide film 155 and the nitride film 145 are removed using H₂SO₄. In some embodiments, the oxide film 155 and the nitride film 145 are simultaneously removed. In addition, a width of a lower part of the second recess 160 is greater than that of an upper part of the second recess 160 in a longitudinal direction of the active region 101 shown in FIG. 4.

Accordingly, a method for fabricating a semiconductor device in accordance with an embodiment of the present invention can obtains an additional channel length and decreases a height of the silicon horn formed at a sidewall of both device isolation structures in a longitudinal direction of the gate region 103 shown in FIG. 4.

In addition, subsequent processes such as a process for forming a gate, a process for forming a spacer on a sidewall of the gate, an ion-implantation process for forming source/drain regions in the active regions, a process for forming a landing plug, a process for forming a bit line contact and a bit line, a process for forming a capacitor, and a process for forming an interconnect may be performed.

As described above, a method for fabricating a semiconductor device in accordance with an embodiment of the present invention provides oxidizing the semiconductor substrate at the bottom of the recess formed in the semiconductor substrate, and removing it, thereby easily increasing a gate channel length. As a result, the short channel effect of the device and the refresh characteristic can be improved. In addition, the height of the silicon horn formed at the sidewall of both device isolation structures in the recess is reduced to secure substantial threshold voltage of the device. As a result, concentration for the channel ion implantation is reduced. Accordingly, an E-field in the junction region and refresh characteristic of the device can be improved.

The foregoing description of various embodiments of the invention has been presented for purposes of illustration and description. It is not intended to be exhaustive or to limit the invention to the precise form disclosed, and modifications and variations are possible in light of the above teachings or may be acquired from practice of the invention. The embodiments were chosen and described in order to explain the principles of the invention and its practical application to enable one skilled in the art to utilize the invention in various embodiments and with various modifications as are suited to the particular use contemplated.

What is claimed is:

1. A method for fabricating a semiconductor device comprising:
forming a first recess in a semiconductor substrate, the first recess having a bottom and a sidewall, the recess being formed within an active region defined by the semiconductor substrate;
forming an insulating film over the substrate and the first recess;
etching the second insulating film to expose a portion of the substrate provided directly below the bottom of the first recess;
oxidizing the exposed semiconductor substrate at the bottom of the first recess to form an oxide film; and
removing the oxide film to form a second recess, wherein a lower portion of the second recess is larger than that of the first recess.

2. The method of claim 1, wherein the insulating film remains on the sidewall of the first recess after the etching step.

3. The method of claim 2, wherein a width of the lower portion of the second recess is greater than that of an upper portion of the second recess in a longitudinal direction of the active region.

4. The method of claim 1, wherein the insulating film is a nitride film.

5. The method according to claim 1, wherein the forming-a-first-recess step includes:
forming a hard mask layer over the semiconductor substrate;
etching the hard mask layer using a recess gate mask to define a gate region to form a recess region; and
etching the semiconductor substrate exposed at a lower part of the recess region to form the first recess.

6. The method according to claim 5, wherein the hard mask layer is formed of a polysilicon layer.

7. The method according to claim 1, wherein the insulating film is a nitride film having a thickness of about 300 Å to about 500 Å.

8. The method according to claim 1, wherein the etching step includes:
forming a photoresist film over an entire surface of the resultant including the insulating film;
exposing and developing the photoresist film using the recess gate mask to a photoresist film pattern exposing the insulating film at the bottom of the first recess; and
etching the exposed insulating film at the bottom of the first recess to expose the portion of the semiconductor substrate beneath the bottom of the first recess,
wherein a width of the exposed first recess between the photoresist film patterns is less than that of the recess gate mask in a longitudinal direction of the active region so that a thickness of the insulating film remains at the sidewall of the first recess.

9. The method according to claim 8, wherein the thickness of the insulating film remaining at the sidewall of the first recess is no more than about 100 Å.

10. The method according to claim 1, wherein the etching step involves an anisotropic etch method.

11. The method according to claim 1, wherein the oxidizing process is performed using a LOCOS oxidation method.

12. The method according to claim 1, wherein the oxidizing process for the exposed semiconductor substrate at the bottom of the first recess is performed at an atmosphere of H₂:O₂ mixture gas, where a ratio of the H₂:O₂ mixture gas ranges from about 7:4 to about 9:6, at a temperature ranging from about 1000° C. to about 1100° C. for about 30 minutes to about 50 minutes.

13. The method according to claim 1, wherein the removing step is performed using a sulfuric acid (H₂SO₄).

14. The method according to claim 1, further comprising filling the second recess to form a gate electrode.
